(19) United States
(12) Patent Application Publication
(10) Pub. No.: US 2026/0106117 A1
(43) Pub. Date: Apr. 16, 2026

(54) DEPOSITION SYSTEM WITH MIXER AND PLASMA BYPASS ORIFICE

(71) Applicant: Applied Materials, Inc., Santa Clara, CA (US)

(72) Inventors: Sandeep Kumpala, Bangalore (IN); Shashank Sharma, CHHATTISGARH (IN); Manjunath Veerappa Chobari Patil, Bengaluru (IN); Sandesh Hemadri, Hubli (IN); Manjunathagoud Bagavad, KARNATAKA (IN); Abhishek Umesh Anvekar, Karwar (IN); Mayur Govind Kulkarni, Bangalore (IN); Ganesh Balasubramanian, Fremont, CA (US); Rohit Bansal, Bangalore (IN); Vijay Ramchandra Gole, Maharashtra (IN)

(21) Appl. No.: 18/990,115

(22) Filed: Dec. 20, 2024

(30) Foreign Application Priority Data
Oct. 16, 2024 (IN) 202441078565

(51) Int. Cl. H01J 37/32; C23C 16/455

(52) U.S. Cl. CPC H01J 37/32449; C23C 16/45544; H01J 2237/332

(57) ABSTRACT

An apparatus includes: a faceplate having upper and lower surfaces, through holes extending from the upper to lower surface; a gas box supported by the faceplate, a first cavity extending from the upper surface of the faceplate to an upper surface of the gas box; an isolator on the upper surface of gas box, a second cavity extending from a lower surface of the isolator to an upper surface of the isolator and a third cavity extending from an outer surface of the isolator to the second cavity; a mixer suspended in a groove in the upper surface of the isolator, the mixer including blades alternatingly arranged on a shaft; and tubing fluidically coupled to a plasma source, the tubing terminating at the upper surface of the isolator. The first and second cavities can be fluidically coupled, and the third cavity can be fluidically coupled to a precursor source.

### BACKGROUND

The present disclosure generally relates to a system and an apparatus for deposition in semiconductor processing.

Generally, chemical vapor deposition (CVD) and atomic layer deposition (ALD) are used in semiconductor manufacturing processes are used to deposit layers that conformally coat an exposed surface of a substrate. CVD is a technique for the deposition of metallic, ceramic, and semiconducting thin films by depositing solid on to a heated surface by a chemical reaction from the vapor or gas phase. ALD is a self-limiting gas-phase chemical deposition technique for the formation of atomic-scale thin films of metals, oxides, polymers or others on substrates (e.g., biomolecules, ceramics, polymers or carbon materials).

### SUMMARY

In a general aspect, an apparatus includes: a faceplate having upper and lower surfaces, a plurality of through holes extending from the upper surface to the lower surface; a gas box supported by the faceplate, a first cavity extending from the upper surface of the faceplate to an upper surface of the gas box; an isolator disposed on the upper surface of gas box, a second cavity extending from a lower surface of the isolator to an upper surface of the isolator and a third cavity extending from an outer surface of the isolator to the second cavity; a mixer suspended in a groove in the upper surface of the isolator, the mixer including a plurality of blades alternatingly arranged on a shaft; and tubing fluidically coupled to a plasma source, the tubing terminating at the upper surface of the isolator. The first and second cavities can be fluidically coupled, and the third cavity can be fluidically coupled to a precursor source.

In another general aspect, a system includes: a gas panel including a plurality of gases connected to respective delivery channels; a first processing chamber fluidically coupled to the gas panel through the respective delivery lines; a second processing chamber separated from the first processing chamber and fluidically coupled to the gas panel through the respective delivery lines; a plasma source fluidically coupled to the gas panel through one of the respective delivery channels and configured to deliver the cleaning gas, the plasma source being fluidically coupled to the first and second processing chambers; and a controller configured to control flow of the plurality of gases and states of the bypass valve and first and second orifices.

In another general aspect, a system includes: a gas panel including a plurality of gases connected to respective delivery channels, the plurality of gasses including a deposition gas, a cleaning gas, and a purge gas; a valve block including a first valve fluidically coupled to the deposition gas, a second valve fluidically coupled to the purge gas, and a third valve fluidically coupled to the first valve and a first orifice, the first and second valves being fluidically coupled to a processing chamber; a plasma source fluidically coupled to the gas panel through one of the respective delivery channels configured to deliver the cleaning gas; and a controller configured to control flow of the plurality of gases and states of the bypass valve and first and second orifices. A bypass valve and the second orifice can be fluidically coupled to the plasma source in a closed loop, the plasma source being fluidically coupled to the processing chamber.

In some implementations, the first cavity has a partially tapered shape, the first cavity being widest proximate to the upper surface of the faceplate.

In some implementations, the first cavity and the second cavity meet at an acute angle in a range of 20 to 60° degrees.

In some implementations, at least a portion of the plurality of blades of the mixer have a semicircular cross-section when viewed along a vertical direction.

In some implementations, at least a portion of the plurality of blades of the mixer have a trapezoidal cross-section when viewed along a horizontal direction.

In some implementations, the gas box includes heat exchangers configured to maintain a temperature within the gas box above 70° C.

In some implementations, the tubing includes a radiofrequency (RF) ground source, and the gas box includes an RF hot source.

In some implementations, a pattern of the through holes includes about 3000 holes.

In some implementations, the plasma source includes oxygen.

In some implementations, during deposition, the bypass valve is configured to be closed, and the second orifice is configured to be open.

In some implementations, a cycle time between the deposition and the cleaning is one second or less.

In some implementations, the second orifice includes aluminum.

In some implementations, the cleaning gas includes nitrogen trifluoride and argon.

In some implementations, the deposition gas includes argon.

In some implementations, the respective delivery channels for the deposition gas and the plasma source combine before entering the processing chamber.

In some implementations, the system further includes a mixer configured to mix the deposition gas and the plasma source.

Advantages may optionally include one or more of the following. A plasma enhanced ALD process can have an increased rate of reaction, thereby increasing throughput and lowering the thermal budget. A low-volume system footprint can be maintained while still obtaining high fluid conductance flow paths to maintain fast cycle times while maintaining film thickness uniformity.

Other aspects, features, and advantages will be apparent from the description and drawings, and from the claims.

### BRIEF DESCRIPTION OF THE DRAWINGS

FIG. 1 illustrates a schematic view of a processing system.

FIG. 2 depicts a perspective view of a gas delivery module above a chamber, which is coupled to a factory interface.

FIG. 3 is a cross-sectional view of a schematic of the gas delivery module and the chamber along line A-A′ of FIG. 2.

FIGS. 4A, 4B, and 4C depict different views of a mixer module of FIG. 3.

FIG. 5A depicts a diagram of gas flow in the processing system of FIG. 1.

FIG. 5B depicts a portion of the diagram of FIG. 5A.

Like reference symbols in the various drawings indicate like elements.

### DETAILED DESCRIPTION

Certain deposition processes remain a challenge in the semiconductor industry. For example, high aspect ratio gap fill applications and highly conformal blanket film deposition are generally performed using chemical vapor deposition (CVD) and atomic layer deposition (ALD), which come with certain disadvantages, such as gas mixing nonuniformity during ALD, thereby reducing wafer quality. For example, gas mixing nonuniformities can lead to film nonuniformity. It is desirable to deposit films uniformly such that thickness variation is minimized across the surface of the substrate. For example, it may be desirable to form films having thickness variation of less than about 5% across the surface of the substrate.

The present disclosure provides a plasma enhanced ALD process that increases the rate of reaction, thereby increasing throughput and lowering the thermal budget. The disclosed structure, e.g., flow paths, can maintain a low-volume system footprint with high conductance flow paths to maintain fast cycle times while maintaining or improving film thickness uniformity.

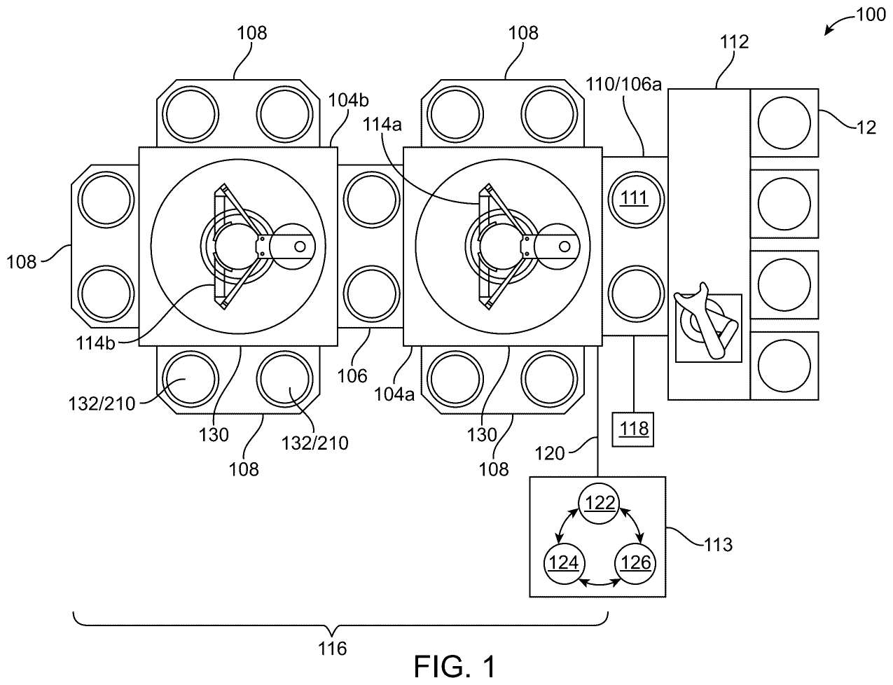

FIG. 1 illustrates a schematic view of an example of a processing system 100 for processing a substrate. The processing system 100 includes two transfer chambers 104a and 104b, a substrate hand-off station 106, and one or more processing modules 108. The processing system 100 may also include a load lock chamber 110, a factory interface 112, and a controller 113. The factory interface 112 is configured to load and unload substrates from the processing system 100, e.g., from cassettes 12 that engage the factory interface 112. The factory interface 112 may include various robots and load ports adapted to load substrates to be processed and to store substrates that have been processed.

The load lock chamber 110 couples the transfer chamber 104a to the factory interface 112. Transfer chamber 104a includes a robot 114a to transfer the substrates into and out of substrate the load lock chamber 110, the hand-off station 106, and the processing modules 108. Similarly, transfer chamber 104b includes a robot 114b to transfer the substrates into and out of substrate hand-off stations 106 and processing modules 108. A front-plate 130 defines a boundary between each transfer chamber 104a, 104b and each respective adjoining processing module 108.

In some implementations, the load lock chamber 110 also functions as a substrate hand-off station 106a that is configured to rotate a substrate. The substrate hand-off station 106a and the one or more processing module 108 are in fluid communication with the transfer chamber 104a.

Each processing module 108 is coupled to one of the transfer chambers 104a, 104b. One or more of the processing modules can be a dual processing module 108 with two processing chambers, e.g., two deposition chambers or treatment chambers. In some implementations, the processing modules 108 include an atomic layer deposition (ALD) deposition chamber. Examples of other suitable deposition chambers that can be included in a processing module 108 include, but are not limited to, a chemical vapor deposition (CVD) chamber, a spin-on coating chamber, a flowable CVD chamber, a physical vapor deposition (PVD) chamber, an epitaxial deposition chamber, and the like. Examples of treatment chambers include, but are not limited to, a thermal treatment chamber, an annealing chamber, a rapid thermal anneal chamber, a laser treatment chamber, an electron beam treatment chamber, a UV treatment chamber, an ion beam implantation chamber, an ion immersion implantation chamber, or the like.

The substrate hand-off station 106 is coupled to the transfer chambers 104a, 104b. The substrate hand-off station 106 separates transfer chamber 104a from transfer chamber 104b. The substrate hand-off station 106 allows for fluid communication between transfer chambers 104a, 104b, such that a substrate being transferred from transfer chamber 104a to transfer chamber 104b passes through the substrate hand-off station 106. The substrate hand-off station 106 can include one or more supports 111, each configured to rotate a substrate.

Continuing to refer to FIG. 1, the processing module 108, the substrate hand-off station 106, the transfer chambers 104a, 104b, and the load lock chamber 110 are connected to form a vacuum tight platform 116. One or more pump systems 118 are coupled to the load lock chamber 110, the transfer chambers 104a, 104b, the substrate hand-off station 106, and the processing modules 108. In FIG. 1, a single pump system 118 is shown coupled to the load lock chamber 110 to avoid drawing clutter. The pump system 118 controls the pressure within the processing system 100. The pump system 118 may be utilized to pump down and vent the load lock chamber 110 as needed to facilitate entry and removal of substrates from the vacuum tight platform 116.

The processing system 100 is coupled to the controller 113 by a communication cable 120. The controller 113 is operable to control processing of a substrate within the processing system 100. The controller 113 includes a programmable central processing unit (CPU) 122 that is operable with a memory 124 and a mass storage device, an input control unit, and a display unit (not shown), such as power supplies, clocks, cache, input/output (I/O) circuits, and the like, coupled to the various components of the processing system 100 to facilitate control of the processes of processing a substrate. The controller 113 may also include hardware for monitoring the processing of a substrate through sensors (not shown) in the processing system 100.

To facilitate control of the processing system 100 and processing a substrate, the CPU 122 may be one of any form of general purpose computer processors for controlling the substrate process. The memory 124 is coupled to the CPU 122 and the memory 124 is non-transitory and may be one or more of readily available memory such as random access memory (RAM), read only memory (ROM), floppy disk drive, hard disk, or any other form of digital storage, local or remote. Support circuits 126 are coupled to the CPU 122 for supporting the CPU 122 in a conventional manner. The instructions for processing a substrate are generally stored in the memory 124. The instructions for processing a substrate may also be stored and/or executed by a second CPU (not shown) that is remotely located from the hardware being controlled by the CPU 122.

The memory 124 is in the form of computer-readable storage media that contains instructions, that when executed by the CPU 122, facilitates the operation of processing a substrate in the processing system 100. The instructions in the memory 124 are in the form of a program product such as a program that implements the operation of processing a substrate. The program code may conform to any one of a number of different programming languages. In one example, the disclosure may be implemented as a program product stored in computer readable storage media for use with a computer system. The program(s) of the program product define functions of the embodiments. Illustrative computer-readable storage media include, but are not limited to: (i) non-writable storage media (e.g., read-only memory devices within a computer such as CD-ROM disks readable by a CD-ROM drive, flash memory, ROM chips or any tope of solid-state non-volatile semiconductor memory) on which information is permanently stored; and (ii) writing storage media (e.g. floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

Although FIG. 1 depicts a processing system 100 including two transfer chambers 104a and 104b, other implementations are possible. For example, the processing system can include one, or three or more, transfer chambers. In some implementations, instead of load lock chamber 110 connecting the factory interface 112 to the transfer chamber 104a, a rotation module including platforms can connect the transfer chamber 104a to the factory interface 112. In general, more details about the processing system 100 can be found in U.S. Pat. No. 10,431,480, which is hereby incorporated by reference.

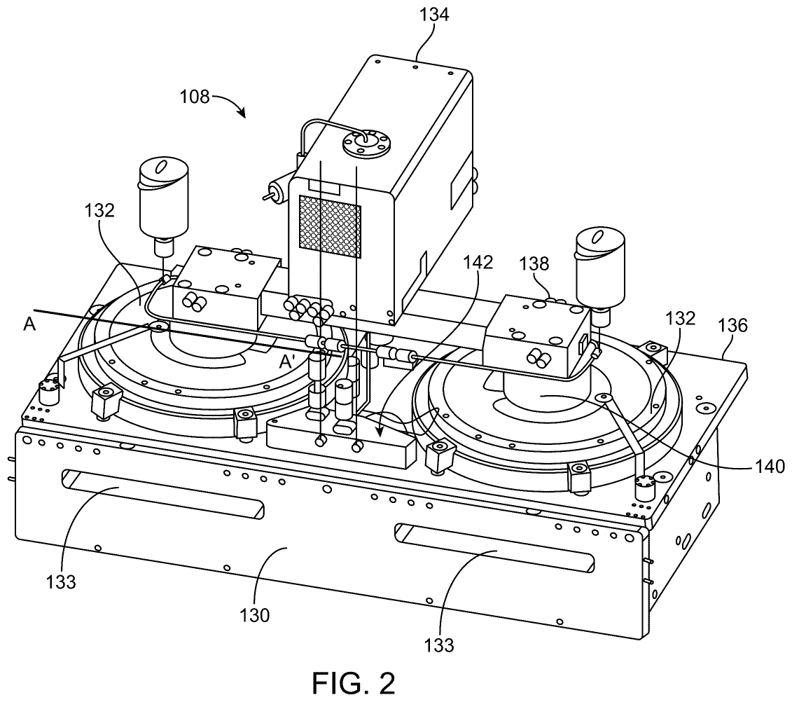

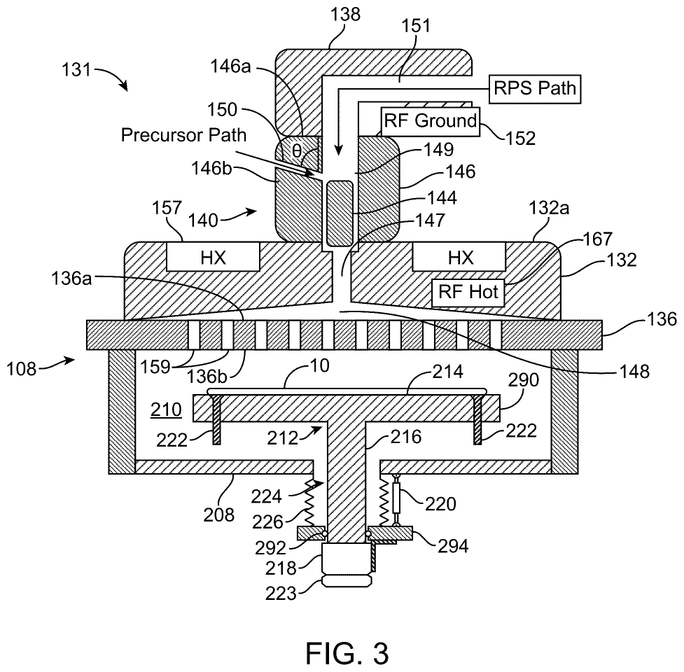

FIG. 2 depicts a perspective view of a dual processing module 108 with two processing chambers. The dual processing module 108 is connected to the transfer chamber 104a or 104b by the front-plate 130, which can serve as a wall between the transfer chamber 104 and the processing module 108. Within the dual processing module 108 are two processing chambers 210 (see FIGS. 1 and 3). Substrates can be inserted from the transfer chamber 104a, 104b into the processing chambers 210 through slots 133, e.g., slit valves, in the front-plate 130 by a robot 114a,114b. Within the processing chamber 210 is a platform, e.g., with a receiving surface 214 (see FIG. 3) onto which the substrate will be delivered from the slot 133.

On each side of the dual processing module 108, a gas box 132 is disposed on a faceplate 136 above a respective processing chamber 210. The gas box 132 has an interior passage 147 (see FIG. 3) that connects to a duct 138 connecting a respective gas box 132 to a remote plasma source (RPS) 134. The RPS 134 can serve as a common plasma source for both gas boxes 132 in the dual processing module 108. In some implementations, the plasma generated by the RPS 134 is high-power O₂ plasma.

In each flow path from the RPS 134 to a respective gas box 132 is a mixer module 140.

FIG. 3 is a cross-sectional view of a schematic of the gas delivery module 131 and one processing chamber from the dual processing module 108 along line A-A′ of FIG. 2. The mixer module 140 includes a mixer 144 surrounded by an isolator 146. An upper surface 146a of the mixer module 140 is fluidically coupled to the duct 138, providing a remote plasma flow path that extends from the RPS 134 through the passage 151 of the duct 138 to the mixer module 140. The mixer module 140 includes a main passage 149 that couples the duct 138 to the gas box 132. A side passage 150 extends from an outer surface 146b of the mixer module 140 to the main passage through the mixer module 140 and provides a precursor path for precursor gas to be injected into the mixer module 140. Relative to the remote plasma path at the end of the duct 138 and in the main passage 149 in the mixer module 140, the precursor path forms an acute angle θ.

In order to prevent condensation of the precursor, which can start to condense at 70° C., a radio frequency (RF) ground 152 can be incorporated into the duct 138 and a higher RF voltage electrode 167, e.g., RF “hot”, can be positioned in the gas box 132. In this example, RF hot refers to a high voltage surface, and RF ground is a low voltage surface. RF hot can alternate at about 13.56 MHz.

In some implementations, a heat exchanger (HX) 157 containing liquid can be disposed in thermal contact with the gas box 132. For example, the heat exchanger 157 can be disposed in an upper part of the gas box 132 and be separated from an interior volume 148 of the gas box 132 by a portion of the body of the gas box 132. In some implementations, an upper surface 132a of the gas box 132 is formed by a surface of the heat exchangers 157, as depicted in FIG. 3. In some implementations, using a hybrid heater lift can lead to longer strokes to reach lower process volumes for faster gas evacuations, which can lead to higher throughput and reduce transient thermal effects on the faceplate 128. Additionally, the series connection of process cooling water (PCW) and the heat exchanger can reduce the amount of coolant used.

The gas box 132 sits on the faceplate 136 so that the combination of gas box 132 and faceplate 136 forms a showerhead assembly for delivery of a mixture of the remotely-generated plasma and precursor into the processing chamber 210. The internal surfaces of the gas box 132 and the faceplate 136 define the shape of the interior volume 148, which is partially tapered, e.g., partially conical. For example, a width of the interior volume 148 is greatest where the interior volume meets the faceplate 128 and narrowest on a side of the cavity near to where the gas box 132 meets the mixer module 140. The interior volume 148 including a tapered section can increase how quickly the mixture of precursor and plasma flow. For example, the design can enable rapid pulsing times between liquid precursor and oxidizing plasma, e.g., one second or less. Maintaining incoming liquid and/or vapor using a heater/heater jacket can prevent condensation temperature of at 105° C. The interior volume 148 is fluidically coupled to the outlet of the mixer module 140 by a vertical passage 147 through the gas box 132.

In operation, the precursor and plasma flow along the flow path and around the mixer 144. For example, the flow path surrounds the mixer 144 and sidewalls of the isolator 146.

A mixture of the precursor and the remotely-generated plasma can reach a substrate in the processing chamber 210 of the dual processing module 108 by flowing through through-holes 159 in the faceplate 136. The through-holes 159 extend from an upper surface 136a of the faceplate 136 facing the gas box 132 to a lower surface 136b of the faceplate 136 facing the processing chamber 210. The through-holes 159 can help increase plasma uniformity when the plasma reaches the workpiece in the load lock chamber 110. In some implementations, there can be thousands of through holes, e.g., 3000 through holes.

The substrate support assembly 212 includes a platform 290, a shaft 216, and a rotary actuator 218. The platform 290 has a substrate receiving surface 214 for to receiving a substrate 10. The shaft 216 extends through the bottom 208 of the chamber body 202 through an opening 224. The opening 224 is sealed by a bellows 226. A plate 294 is coupled to the bellows 226 and surrounds the shaft 216. A shaft seal 292 is a sliding seal that provides a vacuum-tight coupling between the plate 294 and the shaft 216 during actuation of the shaft. The shaft 216 is coupled to the platform 290. In some implementations, the substrate support assembly 212 further includes a plurality of lift pins 222. The plurality of lift pins 222 are configured to be vertically moved by an actuator to extend through the substrate receiving surface 214 to raise and/or lower the substrate to facilitate robotic transfer.

The rotary actuator 218 may be a stepper motor, a servomotor, or the like. In some implementations, the substrate support assembly 212 further includes a rotation sensor 223. The rotary actuator 218 is coupled to the shaft 216 of the substrate support assembly 212. The rotary actuator 218 may be configured to rotate the substrate support assembly 212. The rotation sensor 223 is coupled to the rotary actuator 218. The rotation sensor 223 measures the rotation of the substrate support assembly 212. The rotation sensor 223 may be coupled to the controller to provide real time feedback to the controller. In some implementations, the rotation sensor 223 is an encoder.

In some implementations, the substrate support assembly 212 further includes a vertical actuator 220. The vertical actuator 220 is configured to move the shaft 216 vertically, in a z-direction, so that the platform 290 is raised and or lowered. In FIG. 3, the platform 290 is shown in a raised position.

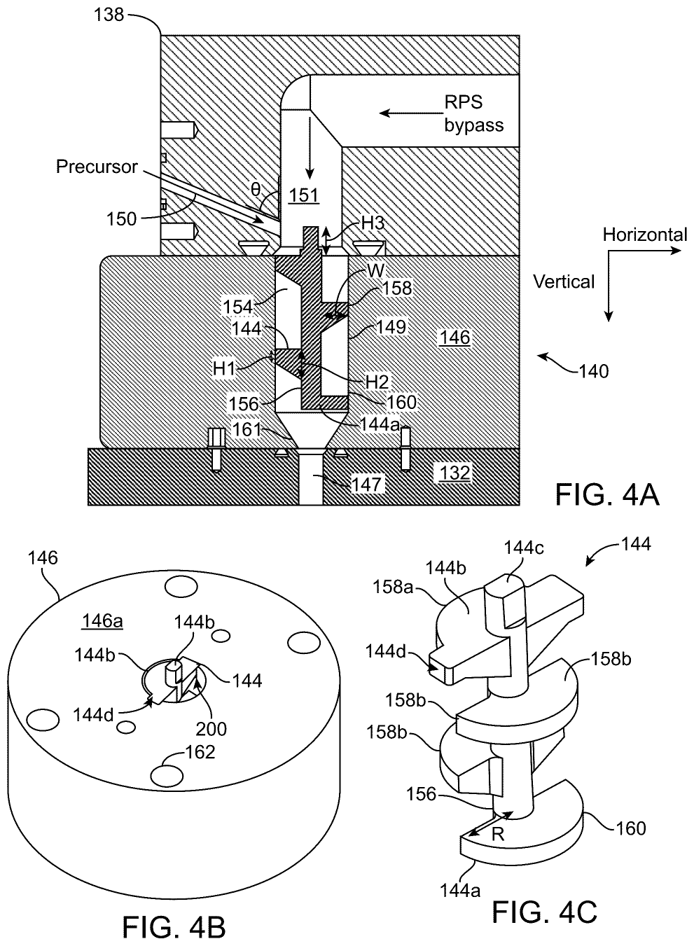

FIGS. 4A, 4B, and 4C depict different views of various components of the mixer module 140. FIG. 4A is a cross-section like FIG. 3 of the mixer module 140 situated between the ducts 138 and the gas box 132. The passages 151 and 150 for the remote plasma and precursor, respectively, meet at an angle θ. For example, the angle can be in a range of about 20° to 60°, which can help insure uniform mixing.

As depicted in FIG. 4A, the mixer 144 and the interior surface of the passage 149 through the isolator 146 define a sinuous or helical flow path through spaces 154. The mixer can include a plurality of baffles that repeatedly redirect the direction of flow of the gas to promote mixing of the plasma and precursor gas. The flow path through spaces 154 begins where the precursor and plasma gases begin to mix, e.g., the top of the mixer 144, and ends where the mixer 144 ends. In some implementations, the isolator 146 is an insulating material, such as ceramic. Below the mixer 144 the passage 149 narrows to form a tapered volume 161 that connects to the passage 147 in the gas box 132.

In the example of FIGS. 4A-4C, the mixer 144 includes a vertical shaft 156 with blades 158 attached to the shaft 156. The blades 158 extend from the shaft 156 on alternating sides along the length of the shaft 156, e.g., on the left and right side of the shaft 156 as shown in FIG. 4A. In other words, each of the blades 158 is rotated 180° relative to the adjacent blade along the vertical direction. In the cross-section of FIG. 4A, each blade 158 has a trapezoidal cross-section, e.g. having a maximum width W along the horizontal direction and a changing height along the vertical direction, e.g., from H1 to H2. A bottom surface 144a of the mixer 144 is defined by a non-angled lowest blade 160, e.g., having the shape of a semicircular prism.

FIG. 4B is a perspective view of the mixer 144 positioned in a passage 145 through the isolator 146. In this example, an upper surface 144b of the top blade 158 of the mixer 144 is not exactly semicircular. Rather, there two lips 144d extend radially outward from the shaft 156 on each side near the top of the shaft 156. The lips 144d can fit in a recess 200 in the upper surface 146a of the isolator 146 and be supported by the floor of the recess 200 so that the remaining lower portion of the mixer 144 is suspended in the passage 145. The tolerances between the mixer 144 and the isolator 146 can be selected to avoid any rubbing that can generate particles. Additionally, the upper surface 146a of the isolator 146 can define holes 162 used to attach the isolator 146 to the ducts 138.

FIG. 4C is a perspective view of the mixer 144. As depicted in FIG. 4C, the upper blade 158a has a cross-section corresponding to a semi-circle with a rectangular lip 144d on opposite sides, and lower blades 158b and lowest blade 160 have semicircular cross-sections when viewed along the vertical direction. A mixer 144 includes a protruding portion 144c, on the upper blade 158a, that can be used to support components during installation of the system.

The dimensions of the components of the mixer 144 can vary. For example, a radius R of the semicircular upper surface of the lower blades 158b can be in a range of 11 mm to 13 mm, e.g., about half an inch. The two lengths L1 and L2 of the trapezoidal cross-section of the blades 158 can be 3 mm to 5 mm and 9 mm to 11 mm, respectively. The shaft 156 can roughly correspond to a cylinder with a height of approximately 4 mm and a radius of approximately 7 mm. The height H3 of the protruding portion 144c can be in a range of 10 mm to 15 mm.

Using the mixer module 140 can improve mixing nonuniformity between the precursor and plasma, e.g., by 90% compared to if the mixer was not present. In some implementations, the mixer 144 is composed of a ceramic material, which can lead to lower surface fluoride radical recombination, e.g., reduced by 27% compared to using a metal material. In some implementations, the mixer module 140 can be relatively low-cost and quick to manufacture, e.g., the cost can be reduced by 87% compared to a standard mixer.

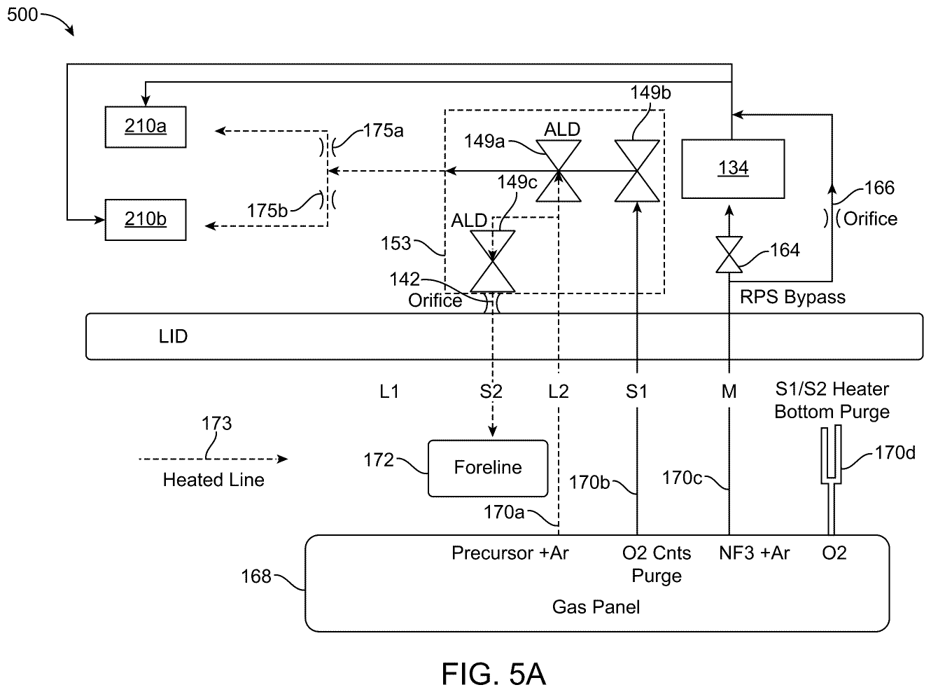

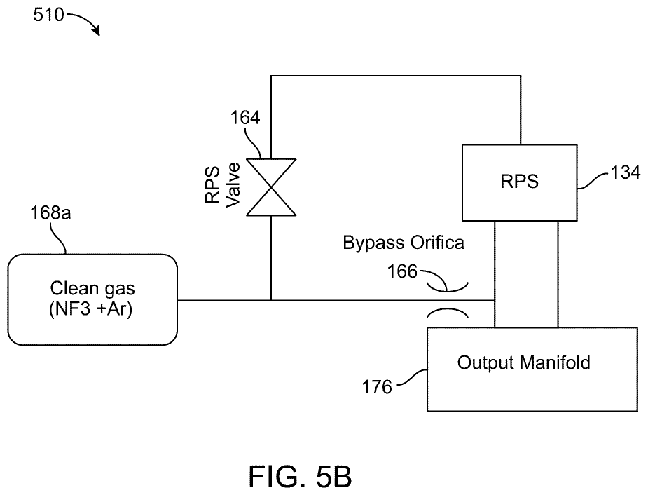

FIG. 5A depicts a diagram 500 of gas flow in the processing system 100. From the RPS 134, a plasma flows to separate chambers 210a and 210b of a dual-processing module 108. Similarly, the precursor and other gases flow from a gas panel 168 through a valve block 153. For example, a precursor gas and an inert carrier gas, e.g., argon, can flow from a line 170a to a valve 149a and then toward orifices 175a and 175b that direct the precursor and argon to the separate platforms 155a and 155b.

A purge gas, e.g., oxygen gas, can flow to a valve 149b via another line 170b. Then the purge gas can flow towards the valve 149a, thereafter following a similar path as the precursor and inert carrier gas. Some of the precursor and carrier gas in line 170a is redirected to a valve 149a, which redirects the gas through an orifice 142 and to a foreline 172. In general, the heated line 173 heats components (marked using the dotted line), e.g., the valve block 153 and line 170a. An O₂ source and S1/S2 heater bottom purge 170d are connected to the heater lift bottom. When valve 149a closes and valve 149c open, gas is redirected toward foreline 172 via valve 149c.

An etchant or cleaning gas, e.g., nitrogen trifluoride (NF3), and a carrier gas, e.g., argon, flow through line 170c and split into either flow toward RPS valve 164 or bypass orifice 166. The RPS bypass valve 164 leads to RPS 134, while following the path including the orifice 166 avoids the RPS 134.

In some implementations, the orifice 166 is composed of aluminum, which can prevent undesired reactions. For example, highly electronegative fluorine radicals react with stainless steel (SST) components, leading to particle generation defects on the workpiece. By using an aluminum orifice 166, diffusion of fluorine radicals toward SST components can be prevented. In general, diffusion of gases governed by gradients of concentration and flow velocity. When there is choked flow, increasing the velocity in the bypass path can increase the Peclet number, e.g., Pe>>1, which reduces the chance of back diffusion.

In some implementations, the size of the bypass orifice can be selected to reduce wastage of non-ionized NF3, which helps in abatement management. Based on desired standards, the orifice size can be changed based on the cleaning gas recipe, thereby providing a modular design.

FIG. 5B depicts a diagram 510 of select components of the diagram 500 from FIG. 5A. For example, the cleaning gas, e.g., the NF3 and argon, flow from the gas panel 168a and toward either the RPS valve 164 or the orifice 166. Both the RPS valve 164 and the bypass orifice 166 are fluidically coupled to the RPS 134, which is coupled to the output manifold 176, e.g., the processing chambers.

The bypass orifice 166 provides a high velocity exit for the gas in the bypass path and eliminates the risk of back diffusion by increasing the Peclet number. The bypass orifice 166 also distributes the total flow and sufficiently high ratios between the bypass path and the RPS path.

During the deposition step, the RPS valve 164 is closed, and the bypass orifice 166 is open, e.g., a controller sends instructions to control the state of the bypass orifice and valve. This ensures low fluid flow to avoid back diffusion. During the clean step, the RPS valve 164 is open, and the bypass orifice 166 is open, which allows RPS flow through the bypass path to provide high velocity flow, reduce NF3 waste, and maintain a proper splitting ratio between bypass flow and flow to RPS, thereby maintaining clean efficiency. In some implementations, the valves in the system are fast acting ALD valves, which can reduce the cycle time. The cycle time, e.g., the combined periods of the deposition step and cleaning step, can be relatively low, e.g., one second or less.

By sharing the RPS clean path between the twin chamber, e.g., output manifold 176 including both platforms 155a and 155b, the overall flow path volume is advantageously reduced. Additionally, back diffusion of precursor species in the RPS path can reduce purge timings, thereby reducing transient times. Additionally, the shared path reduces the infrastructure requirements and provides better serviceability.

While the foregoing is directed to embodiments of the present disclosure, other and further embodiments of the disclosure may be devised without departing from the basic scope thereof, and the scope thereof is determined by the claims that follow.

1. An apparatus comprising:
a faceplate having upper and lower surfaces, a plurality of through holes extending from the upper surface to the lower surface;
a gas box supported by the faceplate, the gas box having an interior volume extending from the upper surface of the faceplate to an upper surface of the gas box;
an isolator disposed on the upper surface of the gas box, the isolator having a first passage extending from a lower surface of the isolator to an upper surface of the isolator and a second passage extending from an outer surface of the isolator to the first passage, wherein the first passage and the interior volume are fluidically coupled, and the second passage is fluidically coupled to a precursor source;
a mixer positioned in the first passage of the isolator, the mixer comprising a plurality of blades alternatingly arranged on a shaft; and
tubing fluidically coupling the upper surface of the isolator to a plasma source.

2. The apparatus of claim 1, wherein a portion of the interior volume has a tapered shape, the portion being widest proximate to the upper surface of the faceplate.

3. The apparatus of claim 1, wherein the first passage and the passage meet at an acute angle in a range of 20 to 60° degrees.

4. The apparatus of claim 1, wherein at least a portion of the plurality of blades of the mixer have a semicircular cross-section when viewed along a vertical direction.

5. The apparatus of claim 1, wherein at least a portion of the plurality of blades of the mixer have a trapezoidal cross-section when viewed along a horizontal direction.

6. The apparatus of claim 1, wherein the gas box comprises heat exchangers configured to maintain a temperature within the gas box above 70° C.

7. The apparatus of claim 1, wherein the tubing comprises a radiofrequency (RF) ground source, and the gas box comprises an RF hot source.

8. The apparatus of claim 1, further comprising a chamber below the faceplate, a platform configured to receive a substrate disposed within an internal cavity of the chamber.

9. The apparatus of claim 1, wherein the plurality of blades are alternatingly arranged on a shaft and form a sinuous path for flow of plasma from the plasma source and precursor gas from the precursor source.

10. The apparatus of claim 1, wherein the plasma source is configured to generate oxygen plasma.

11. A deposition system comprising:
a gas panel comprising a plurality of gases connected to respective delivery channels;
a first processing chamber fluidically coupled to the gas panel through the respective delivery lines;
a second processing chamber separated from the first processing chamber and fluidically coupled to the gas panel through the respective delivery lines;
a plasma source fluidically coupled to the gas panel through one of the respective delivery channels and configured to deliver a cleaning gas, the plasma source being fluidically coupled to the first and second processing chambers; and
a controller configured to control flow of the plurality of gases and states of a bypass valve and first and second orifices.

12. A deposition system comprising:
a gas panel comprising a plurality of gases connected to respective delivery channels, the plurality of gasses comprising a deposition gas, a cleaning gas, and a purge gas;
a valve block comprising a first valve fluidically coupled to the deposition gas, a second valve fluidically coupled to the purge gas, and a third valve fluidically coupled to the first valve and a first orifice, the first and second valves being fluidically coupled to a processing chamber;
a plasma source fluidically coupled to the gas panel through one of the respective delivery channels configured to deliver the cleaning gas, wherein a bypass valve and the second orifice are fluidically coupled to the plasma source in a closed loop, the plasma source being fluidically coupled to the processing chamber; and
a controller configured to control flow of the plurality of gases and states of the bypass valve and first and second orifices.

13. The deposition system of claim 12, wherein, during deposition, the bypass valve is configured to be closed, and the second orifice is configured to be open.

14. The deposition system of claim 13, wherein during cleaning, the bypass valve and the second orifice are configured to be open.

15. The deposition system of claim 14, wherein a cycle time between the deposition and the cleaning is one second or less.

16. The deposition system of claim 12, wherein the second orifice comprises aluminum.

17. The deposition system of claim 16, wherein the cleaning gas comprises nitrogen trifluoride and argon.

18. The deposition system of claim 12, wherein the deposition gas comprises argon.

19. The deposition system of claim 12, wherein the respective delivery channels for the deposition gas and the plasma source combine before entering the processing chamber.

20. The deposition system of claim 13, further comprising a mixer configured to mix the deposition gas and the plasma source.
